(19) United States
(12) Patent Application Publication
(10) Pub. No.: US 2023/0058988 A1
(43) Pub. Date: Feb. 23, 2023

(54) TRANSISTOR

(71) Applicant: Japan Display Inc., Tokyo (JP)

(72) Inventors: Akihiro HANADA, Tokyo (JP); Hajime WATAKABE, Tokyo (JP); Takeshi SAKAI, Tokyo (JP)

(73) Assignee: Japan Display Inc., Tokyo (JP)

(21) Appl. No.: 17/891,162

(22) Filed: Aug. 19, 2022

(30) Foreign Application Priority Data
Aug. 20, 2021 (JP) 2021-135020

(51) Int. Cl. H01L 29/786; H01L 29/10; H01L 29/423; H01L 29/417

(52) U.S. Cl. CPC H01L 29/7869; H01L 29/1095; H01L 29/42364; H01L 29/41725

(57) ABSTRACT

According to one embodiment, a transistor includes a gate electrode, an oxide semiconductor layer which overlaps the gate electrode and including a central portion and an end portion, and a source electrode and a drain electrode each connected to the oxide semiconductor layer, wherein an oxidation degree of the end portion is lower than an oxidation degree of the central portion, and a length of the gate electrode overlapping the central portion is greater than a length of the gate electrode overlapping the end portion.

### CROSS-REFERENCE TO RELATED APPLICATIONS

This application is based upon and claims the benefit of priority from Japanese Patent Application No. 2021-135020 filed Aug. 20, 2021, the entire contents of which are incorporated herein by reference.

### FIELD

Embodiments described herein relate generally to a transistor.

### BACKGROUND

In display devices, a technology has been proposed in which a transistor with an oxide semiconductor is provided in a pixel circuit in a display area, and a transistor with a silicon semiconductor is provided in a drive circuit in a peripheral area.

### BRIEF DESCRIPTION OF THE DRAWINGS

FIG. 1A is a plan view schematically showing an example of a transistor of Embodiment 1.

FIG. 1B is a cross-sectional view of the transistor taken along line A1-A2 shown in FIG. 1A.

FIG. 1C is a cross-sectional view of the transistor taken along line B1-B2 shown in FIG. 1A.

FIG. 2A is a plan view schematically showing an example of a transistor of Comparative Example 1.

FIG. 2B is a cross-sectional view of the transistor taken along line C1-C2 shown in FIG. 2A.

FIG. 2C is a cross-sectional view of the transistor taken along line D1-D2 shown in FIG. 2A.

FIG. 3A is a plan view schematically showing another configuration example of the transistor of

Embodiment 1.

FIG. 3B is a cross-sectional view of the transistor taken along line E1-E2 shown in FIG. 3A.

FIG. 3C is a cross-sectional view of the transistor taken along line F1-F2 shown in FIG. 3A.

FIG. 4A is a plan view schematically showing still another configuration example of the transistor of Embodiment 1.

FIG. 4B is a cross-sectional view of the transistor taken along line G1-G2 shown in FIG. 4A.

FIG. 4C is a cross-sectional view of the transistor taken along line H1-H2 shown in FIG. 4A.

FIG. 5A is a plan view schematically showing an example of a transistor of Comparative Example 2.

FIG. 5B is a cross-sectional view of the transistor taken along line J1-J2 shown in FIG. 5A.

FIG. 5C is a cross-sectional view of the transistor taken along line K1-K2 shown in FIG. 5A.

FIG. 6A is a plan view schematically showing an example of a transistor of Embodiment 2.

FIG. 6B is a cross-sectional view of the transistor taken along line L1-L2 shown in FIG. 6A.

FIG. 6C is a cross-sectional view of the transistor taken along line M1-M2 shown in FIG. 6A.

FIG. 7A is a plan view schematically showing an example of a transistor of Comparative Example 3.

FIG. 7B is a cross-sectional view of the transistor taken along line N1-N2 shown in FIG. 7A.

FIG. 7C is a cross-sectional view of the transistor taken along line 01-02 shown in FIG. 7A.

FIG. 8A is a plan view schematically showing another configuration example of the transistor of Embodiment 2.

FIG. 8B is a cross-sectional view of the transistor taken along line P1-P2 shown in FIG. 8A.

FIG. 8C is a cross-sectional view of the transistor taken along line Q1-Q2 shown in FIG. 8A.

FIG. 9A is a plan view schematically showing still another configuration example of the transistor of Embodiment 2.

FIG. 9B is a cross-sectional view of the transistor taken along line R1-R2 shown in FIG. 9A.

FIG. 9C is a cross-sectional view of the transistor taken along line S1-S2 shown in FIG. 9A.

FIG. 10A is a plan view schematically showing an example of a transistor of Comparative Example 4.

FIG. 10B is a cross-sectional view of the transistor taken along line U1-U2 shown in FIG. 10A.

FIG. 10C is a cross-sectional view of the transistor taken along line V1-V2 shown in FIG. 10C.

### DETAILED DESCRIPTION

In general, according to one embodiment, a transistor comprises a gate electrode; an oxide semiconductor layer which overlaps the gate electrode and including a central portion and an end portion; an insulating layer provided between the gate electrode and the oxide semiconductor layer; and a source electrode and a drain electrode each connected to the oxide semiconductor layer, wherein an oxidation degree of the end portion is lower than an oxidation degree of the central portion; and a length of the gate electrode overlapping the central portion is greater than a length of the gate electrode overlapping the end portion.

According to another embodiment, a transistor comprises a gate electrode; an oxide semiconductor layer overlapping the gate electrode and including a central portion and an edge portion; an insulating layer between the gate electrode and the oxide semiconductor layer; and a source electrode and a drain electrode each connected to the oxide semiconductor layer, wherein an oxidation degree of the central portion is lower than an oxidation degree of the end portion, a length between the source electrode and the drain electrode in the central portion is greater than a length between the source electrode and the drain electrode in the end portion.

According to still another embodiment, a transistor comprises a gate electrode; an oxide semiconductor layer which overlaps the gate electrode and including a central portion and an end portion; an insulating layer provided between the gate electrode and the oxide semiconductor layer; and a source electrode and a drain electrode each connected to the oxide semiconductor layer, wherein an oxidation degree of the end portion is lower than an oxidation degree of the central portion, and a length of the gate electrode which overlaps the end portion is greater than a length of the gate electrode which overlaps the central portion.

According to still another embodiment, a transistor comprises a gate electrode; an oxide semiconductor layer which overlaps the gate electrode and including a central portion and an end portion; an insulating layer provided between the gate electrode and the oxide semiconductor layer; and a source electrode and a drain electrode each connected to the oxide semiconductor layer, wherein an oxidation degree of the end portion is lower than an oxidation degree of the central portion; and a length between the source electrode and the drain electrode in the end portion is greater than a length between the source electrode and the drain electrode in the central portion.

According to still another embodiment, a transistor comprises a gate electrode; an oxide semiconductor layer which overlaps the gate electrode and includes a first region and a second region; an insulating layer provided between the gate electrode and the oxide semiconductor layer; and a source electrode and a drain electrode each connected to the oxide semiconductor layer, wherein an oxidation degree of the first region is lower than an oxidation degree of the second region, and a first channel length of a first channel forming region in the first region is greater than a second channel length of a second channel forming region in the second region.

An object of the embodiments is to provide a transistor which can suppress degradation of characteristics.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Transistors of embodiments will be described in detail with reference to the accompanying drawings. In the embodiments, a first direction X, a second direction Y and a third direction Z are orthogonal to each other, but they may intersect at an angle other than 90 degrees. In the following descriptions, a direction forwarding a tip of an arrow indicating the third direction Z is referred to as “upward” or “above” and a direction forwarding oppositely from the tip of the arrow is referred to as “downward” or “below”. The first direction X, the second direction Y and third direction Z may as well be referred to as an X direction, a Y direction and a Z direction, respectively.

With such expressions “a second member above a first member” and “a second member below a first member”, the second member may be in contact with the first member or may be remote from the first member.

In the latter case, a third member may be interposed between the first member and the second member. On the other hand, with such expressions “a second member on a first member” and “a second member on a first member”, the second member is meant to be in contact with the first member.

In addition, it is assumed that there is an observation position to observe the semiconductor substrate on a tip side of an arrow in the third direction Z, and viewing from this observation position toward the X-Y plane defined by the first direction X and the second direction Y is referred to as a planar view. Viewing a cross section of the transistor in an

X-Z plane defined by the first direction X and the third direction Z or a Y-Z plane defined by the second direction Y and the third direction Z is referred to as a cross-sectional view.

### Embodiment 1

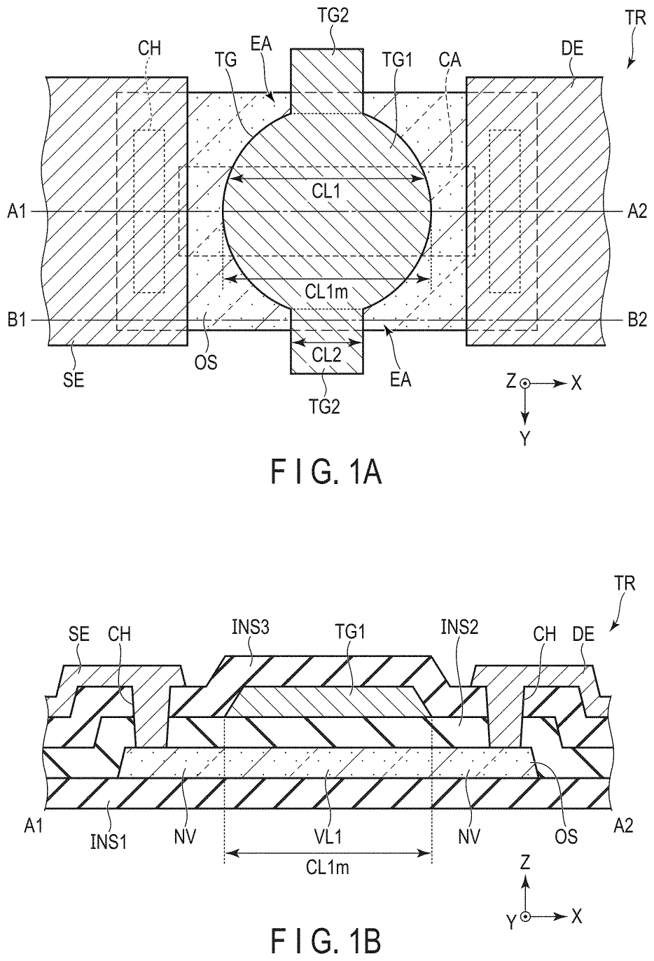

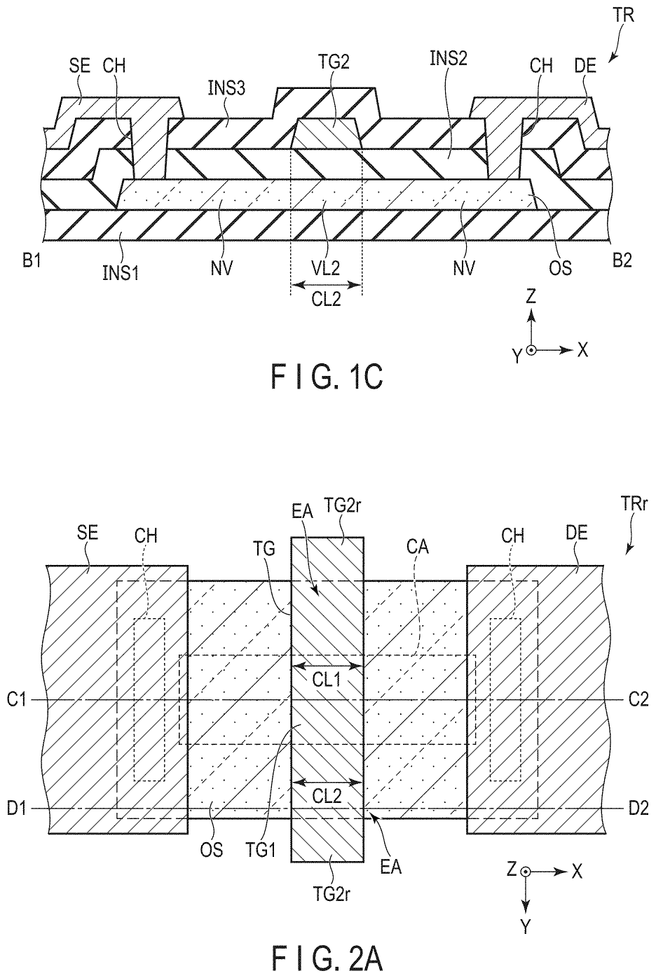

FIG. 1A is a plan view schematically showing an example of the transistor of Embodiment 1. FIG. 1B is a cross-sectional view of the transistor taken along the line A1-A2 shown in FIG. 1A. FIG. 1C is a cross-sectional view of the transistor taken along line B1-B2 shown in FIG. 1A.

The transistor TR comprises an insulating layer INS1, an oxide semiconductor layer OS, an insulating layer INS2, a gate electrode TG, an insulating layer INS3, a source electrode SE and a drain electrode DE.

The oxide semiconductor layer OS has a rectangular shape in the X-Y plane. More specifically, the shape of the oxide semiconductor layer OS is a rectangle in which the length of sides along the first direction X is greater than the length of sides along the second direction Y.

The gate electrode TG extends along the second direction Y and overlaps the oxide semiconductor layer OS. The gate electrode TG is disposed between the source electrode SE and the drain electrode DE in plan view. In the oxide semiconductor layer OS, the regions between the gate electrode TG and the source electrode SE and between the gate electrode TG and the source electrode SE do not overlap any of the electrodes. The gate electrode TG includes a region TG1 and a region TG2. The region TG1 has a shape in which a part of a circle is cut by a string (a segmental arc shape). As shown in FIG. 1A, the region TG1 has a shape in which upper and lower portions of the circular shape are cut by a string with respect to the direction of viewing on the surface of the page. The region TG2 has a rectangular shape.

Lengths of the regions TG1 and TG2, taken along the first direction X are lengths CL1 and CL2, respectively. In FIG. 1A, along the second direction Y, a region TG2, a region TG1 and another region TG2 are arranged side by side. In other words, the region TG1 is interposed between the two regions TG2. More specifically, in the gate electrode TG, the region TG2 having a predetermined length CL2, the region TG1 having a length CL1 variable along the second direction Y and the other region TG2 having a predetermined length CL2 are integrated along the second direction Y into one body.

In the region TG1, the length CL1, which passes through the center of the above-mentioned circular shape takes the longest, which is a length CL1m. As the location approaches the region TG2, the length CL1 becomes shorter. At the boundary of the region TG2, the lengths CL1 and CL2 are equal to each other.

In the oxide semiconductor layer OS, the degree of oxidation differs between a region EA near an end portion in plan view and a region CA near a central portion, which is remote from the end portion. This is because the region EA is more easily accessible to oxygen from the outside compared to the region CA. The region CA is under-oxidized compared to the region EA. That is, the degree of oxidation in the region CA is lower than that of the region EA.

As shown in FIG. 1A, the region TG1 of the gate electrode TG overlaps the region CA of the oxide semiconductor layer. The region TG2 does not overlap the region CA, but overlaps the region EA. In the oxide semiconductor layer OS, a region overlapping the region TG1 and a region overlapping the region TG2 are channel forming regions. The details of the channel forming region will be described later.

As shown in FIGS. 1B and 1C, the oxide semiconductor layer OS is provided on the insulating layer INSl. The insulating layer INS2 is provided over the insulating layer INSl and the oxide semiconductor layer OS. The gate electrode TG is provided to oppose the oxide semiconductor layer OS while interposing the insulating layer INS2 therebetween. The gate electrode TG is a top gate provided above the oxide semiconductor layer OS. As shown in FIGS. 1A to 1C, the length of the oxide semiconductor layer OS along in the first direction X is greater than the length CL1 of the region TG1 and the length CL2 of the region TG2.

The insulating layer INS3 is provided over the gate electrode TG and the insulating layer INS2. The source electrode SE and the drain electrode DE are provided on the insulating layer INS3. The source electrode SE and the drain electrode DE are connected to the oxide semiconductor layer OS via contact holes CH provided in the insulating layers INS3 and INS2, respectively. The distance between the source electrode SE and the drain electrode DE is constant. The gate electrode TG is provided between the source electrode SE, the drain electrode SE and the oxide semiconductor layer OS.

The insulating layers INS1 and INS2 are formed of an inorganic material containing oxygen and nitrogen, for example, silicon oxide. The insulating layer INS1 may be an insulating base material having translucency, for example, glass or resin. Examples of such a resin include polyimide resin and acrylic resin.

The oxide semiconductor layer OS is formed of indium gallium zinc oxide (IGZO), indium gallium zinc oxide (ITZO), zinc oxide nitride (ZnON), indium gallium oxide (IGO) or the like.

The gate electrode TG can be formed using a metal material, for example, a single layer metal film or a stacked film of multiple metal films. Specific examples include a molybdenum-tungsten alloy (MoW) film and a stacked film in which an aluminum alloy film is sandwiched between titanium films.

The insulating layer INS3 may be formed of an inorganic material containing oxygen or nitrogen as described above. Or, if possible, the insulating layer INS3 may be formed of an organic resin material.

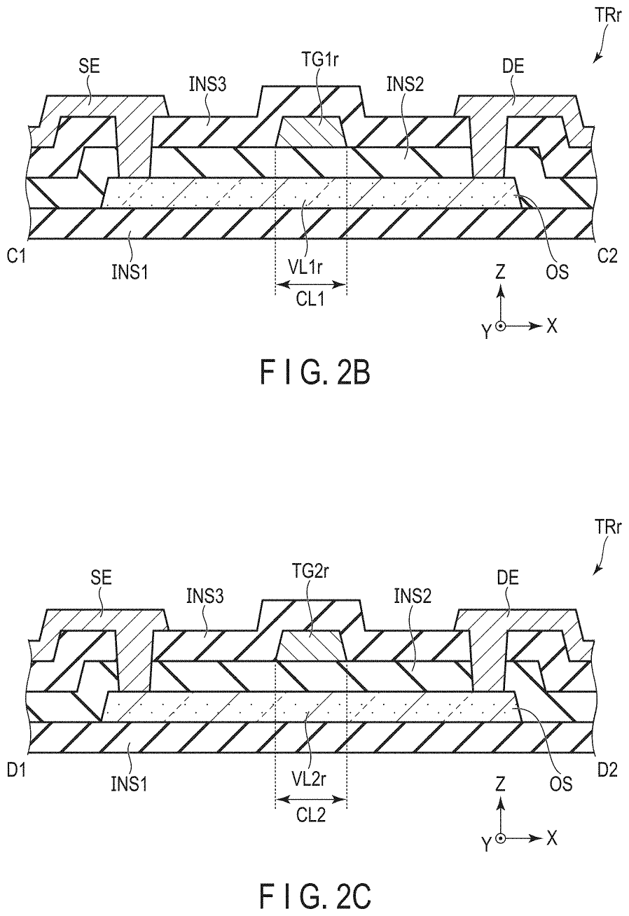

FIG. 2A is a plan view schematically showing an example of a transistor of Comparative Example 1. FIG. 2B is a cross-sectional view of the transistor taken along line C1-C2 shown in FIG. 2A. FIG. 2C is a cross-sectional view of the transistor taken along line D1-D2 shown in FIG. 2A. The gate electrode TG of the transistor TRr in Comparative Example 1 has a constant length along the first direction X.

Of the gate electrode TG, a region overlapping the region CA is a region TG1r, and a region not overlapping the region CA, but overlapping the region EA is a region TG2r. Lengths of the regions TGlr and TG2r along the first direction X are referred to as CL1 and CL2, respectively. The lengths CL1 and CL2 are equal to each other.

In the oxide semiconductor layer OS, the regions overlapping the region TGlr are the channel forming regions VL1r, and the region overlapping region TG2r is the channel forming region VL2r. In other words, the transistor TRr includes two transistors each containing channel forming regions VL1r and VL2r having respective degrees of oxidation different from each other.

In the transistor including the under-oxidized channel forming region VL1r, a parasitic channel may be created, resulting in negatively shifting of the threshold value, which is undesirable. Further, in the channel forming regions VL1r and VL2r, which have different degrees of oxidation, different currents flow, respectively. As a result, the threshold voltages of the two transistors may become undesirably different from each other. This may cause hump characteristics, in which a bend appears in the voltage-current characteristics of the transistor TRr. Therefore, the characteristics of the transistor TRr as a whole may undesirably deteriorate.

With reference back to FIGS. 1A, lA and 1C, the transistors TR of this embodiment will be described. In the oxide semiconductor layer OS of this embodiment, the region which overlaps the region TG1 of the gate electrode TG is defined as a channel forming region VL1, the region which overlaps the region TG2 is defined as the channel forming region VL2, and a region that does not overlap the gate electrode TG is defined as a region NV. The lengths CL1, CL1m and CL 2 are, respectively, the channel length of the channel forming region VL1, the maximum channel length of the channel forming region VL1 and the channel length of the channel forming region VL2. In other words, the lengths CL1, CL1m and CL 2 correspond respectively to the channel length of the channel forming region in the region CA, the maximum channel length of the channel forming region in the region CA, and the channel length of the channel forming region in the region EA. The channel forming region VL1 is formed in the under-oxidized region CA, and therefore negative shift of the threshold value may occur. However, the channel length (length CL1) of the channel forming region VL1 is long, especially, the maximum length CL1m. With this structure, the negative shift of the threshold value can be suppressed.

In the transistor TRr of Comparative Example 1, the channel lengths CL1 and CL2 are equal to each other. Therefore, the under-oxidized channel forming region VL1r has a negative threshold value compared to that of the channel forming region VL2r. Therefore, in the transistor TRr, the channel forming region VL1r and the channel forming region VL2r are connected in parallel, which may cause negative shift of the threshold value and hump characteristics.

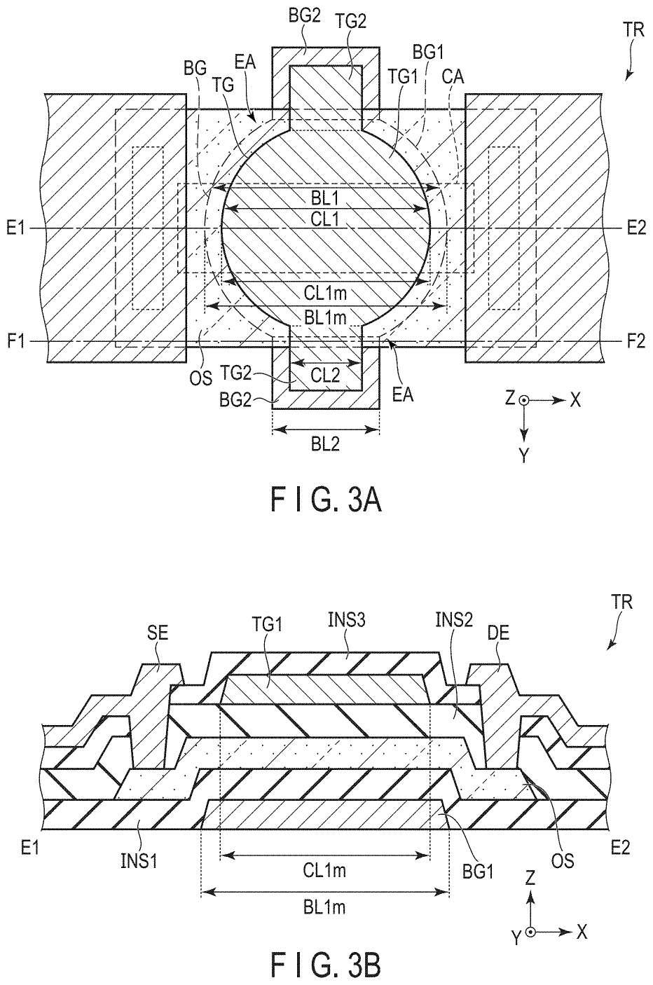

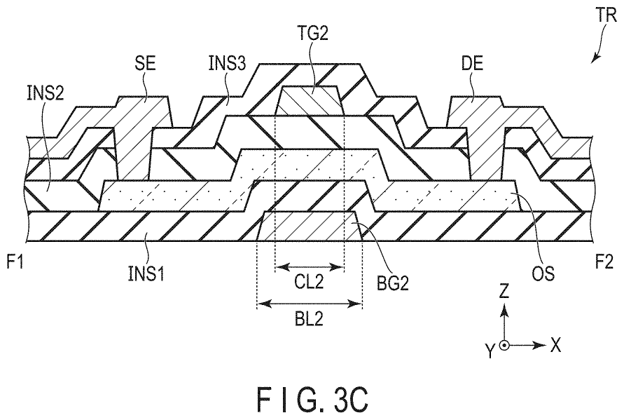

On the other hand, in Embodiment 1, the length CL1, which is a channel length, is greater than the length CL2, which is a channel length. Therefore, even if the transistor contains under-oxidized regions, it is possible to prevent the occurrence of the negative shift of the threshold value and the hump characteristics. Thus, the degradation of the characteristics of the transistor TR can be suppressed. <Configuration Example 1>FIG. 3A is a plan view of another configuration example of the transistor in Embodiment 1. The configuration example shown in FIG. 3A is different from that of FIG. 1A in that it includes a bottom gate in addition to a top gate.

FIG. 3B is a cross-sectional view of the transistor taken along line C1-C2 shown in FIG. 3A. FIG. 3C is a cross-sectional view of the transistor taken along line D1-D2 shown in FIG. 3A. In this configuration example, mainly the points which differ from those of Embodiment 1 will be explained.

The transistor TR comprises a gate electrode BG, an insulating layer INS1, an oxide semiconductor layer OS, an insulating layer INS2, a gate electrode TG, an insulating layer INS3, a source electrode SE and a drain electrode DE. The oxide semiconductor layer OS is provided between the gate electrodes BG and TG. The gate electrode BG is a bottom gate provided below the oxide semiconductor layer OS. That is, the gate electrodes BG and TG are, respectively, a top gate and a bottom gate, or may be a first gate electrode and a second gate electrode, respectively. The oxide semiconductor layer OS is provided between the first gate electrode (TG) and the second gate electrode (BG).

The gate electrode BG has a shape one size larger than that of the gate electrode TG. The gate electrode BG includes a region BG1 and a region BG2. The region BG1 has a shape in which a part of a circle is cut by a string (a segmental arc shape). As shown in FIG. 3A, the region BG1 has a shape in which upper and lower portions of the circular shape are cut by a string with respect to the direction of viewing on the surface of the page. The region BG2 has a rectangular shape. In the region BG1, the length BL1 passing through the center of the above-mentioned circular shape takes the maximum length BL1m. As the location approaches the region BG2, the length BL1 becomes shorter. At the boundary of the region BG2, the lengths BL1 and BL2 are equal to each other.

The gate electrode TG shown in FIG. 3A has a shape similar to that of the gate electrode TG shown in FIG. 1A. The regions TG1 and TG2 overlap the regions

BG1 and BG2, respectively.

As shown in FIG. 3B, an end portion of the region BG1 and an end portion of the region TG1 do not coincide with each other in cross-sectional view. As shown in FIG. 2C, an end portion of the region BG2 and an end portion of the region TG2 do not coincide with each other in cross-sectional view.

The length BL1 is greater than length CL1 at the same location along the second direction Y. Similarly, the length BL1m is greater than the length CL1m. The length BL2 is greater than the length CL2.

When the end portions of the gate electrode BG (the regions BG1 and BG2) and the gate electrode TG (the regions TG1 and TG2) coincide with each other, a large step may be created, and undesirably, the reliability of the transistor TR may be decreased. Therefore, it is preferable that these end portions should not coincide with each other.

The gate electrode BG may be formed of a material similar to that of the gate electrode TG. When the gate electrode BG is formed of a metal material, the gate electrode BG also functions as a light-shielding layer which shields the channel forming region.

In Configuration Example 1, functions similar to those of Embodiment 1 are carried out.

### <Configuration Example 2>

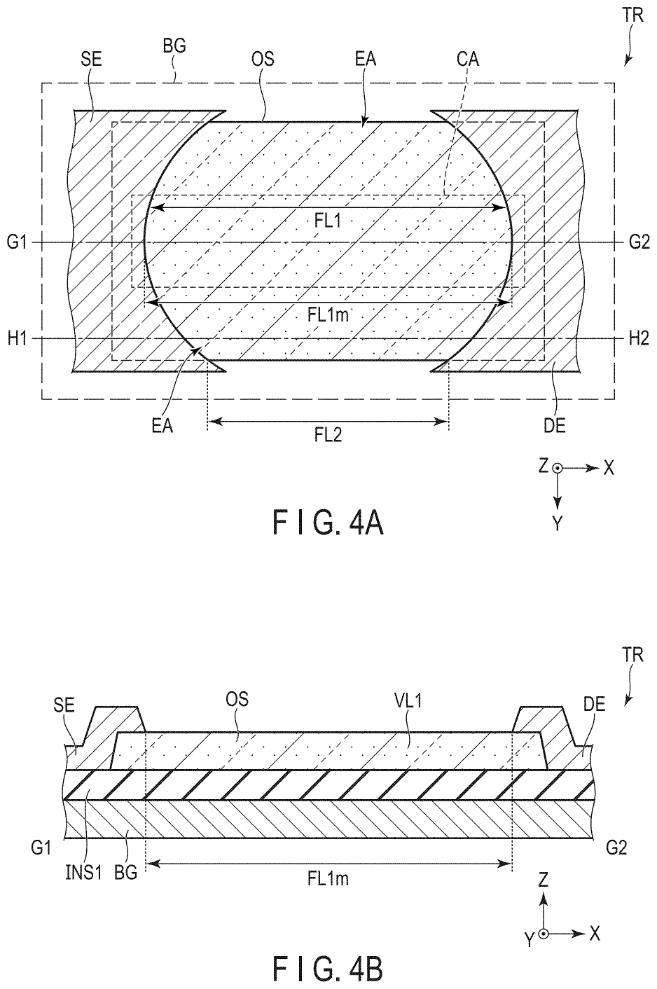

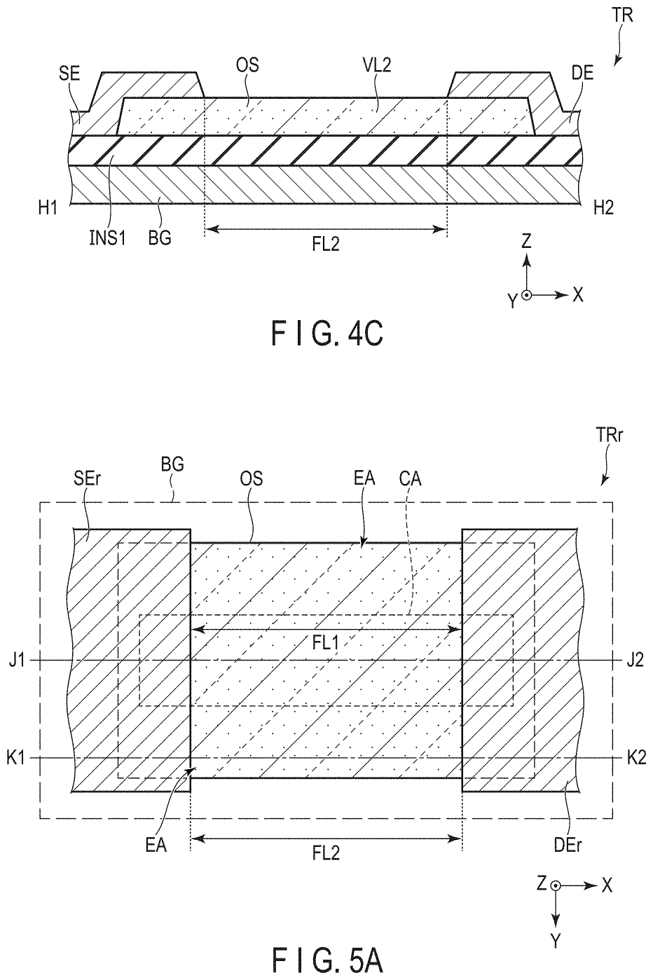

FIG. 4A is a plan view showing another configuration example of the transistor in Embodiment 1. The configuration example shown in FIG. 4A is different from that of FIG. 1A in that it does not includes a top gate but only includes a bottom gate.

FIG. 4B is a cross-sectional view of the transistor taken along line G1-G2 shown in FIG. 4A.

FIG. 4C is a cross-sectional view of the transistor taken along line H1-H2 shown in FIG. 4A.

The transistor TR comprises a gate electrode BG, an insulating layer INS1, a source electrode SE and a drain electrode DE.

The insulating layer INS1 is provided on the gate electrode BG. The oxide semiconductor layer OS is provided on the insulating layer INS1. The oxide semiconductor layer OS opposes the gate electrode BG while interposing the insulating layer INS1 therebetween. The entire oxide semiconductor layer OS overlaps the gate electrode BG.

The source electrode SE and the drain electrode DE are each provided in contact with the oxide semiconductor layer OS. The source electrode SE and the drain electrode DE each have a shape of a rectangle partially notched with an arc. As shown in FIG. 4A, the source electrode SE has a shape in which a right side of a rectangle is notched with an arc relative to the surface of the page. The drain electrode DE has a shape in which a left side of the rectangle is notched with an arc relative to the surface of the page. The two arcs oppose each other. The oxide semiconductor layer OS is provided between the source electrode SE, the drain electrode DE, and the gate electrode BG.

The length between the source electrode SE and the drain electrode DE varies along the second direction Y. In the region CA described above, the length between the source electrode SE and the drain electrode DE is defined as FL1. In the region EA, the length between the source electrode SE and the drain electrode DE is defined as FL2. In the variable length FL1, the maximum length is FL1m. Here, if it is assumed that the above-described opposing arcs form a circle, the length through the center of the circle is FL1m.

In FIGS. 4A, 4B and 4C, the region of the oxide semiconductor layer OS, which overlaps the gate electrode BG and is located between the source electrode SE and the drain electrode DE is the channel forming region. The lengths FL1, FL1m and FL2 are respectively the channel length of the channel forming region VL1 in the region CA, the maximum channel length of the channel forming region VL1 in the region CA and the channel length of the channel forming region VL2 in the region EA.

In the transistor TR shown in FIG. 4A, the length FL1 is equal to the length FL2 at the boundary between the regions CA and EA. As the location approaches the center of the circle, the length FL1 becomes greater, and as described above, the length becomes FL1m at the center of the circle.

The length FL2 takes the maximum length at the boundary between the regions CA and EA. As the location approaches the end portions of the source electrode SE and the drain electrode DE, the length FL2 becomes shorter.

In Configuration Example 2, the length FL1, which is the channel length of the under-oxidized channel forming region VL1, is made greater than the length FL2, which is the channel length of the oxidized channel forming region VL2, and thus the occurrence of the negative shift of the threshold value and the hump characteristics can be prevented. Thus, it is possible to suppress the degradation of the characteristics of the transistor TR.

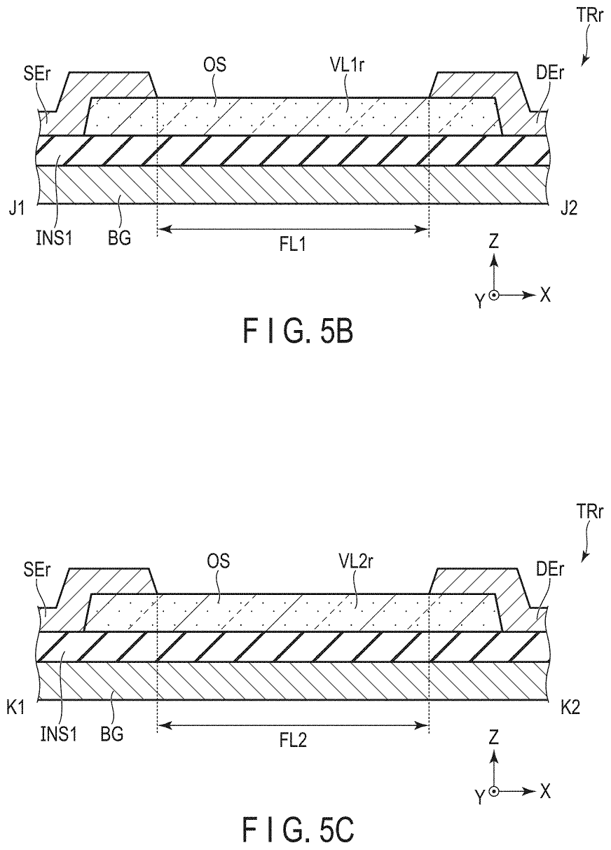

FIG. 5A is a plan view schematically showing an example of a transistor of Comparative Example 2. FIG. 5B is a cross-sectional view of the transistor taken along line J1-J2 shown in FIG. 5A. FIG. 5C is a cross-sectional view of the transistor taken along line K1-K2 shown in FIG. 5A. The region between a source electrode SEr and a drain electrode DEr of a transistor TRr in Comparative Example 2 has a constant length at all times along the first direction X.

In the region between the source electrode SEr and the drain electrode DEr, the partial region overlapping the region CA is the channel forming region VL1r, and the partial region overlapping the region EA is the channel forming region VL2r. In other words, the transistor TRr includes two transistors, each of which contains channel forming regions VL1r and VL2r having degrees of oxidation different from each other.

In the transistor including the under-oxidized channel forming region VL1r, the threshold value may negatively shift. The threshold voltages of the two transistors may be undesirably differ from each other, which may result in hump characteristics in which a bend appears in the voltage-current characteristics of transistor TRr. Thus, degradation in the characteristics of the transistor TRr as a whole may occur undesirably.

As shown in Configuration Example 2, when the channel length (length FL1) of the under-oxidized channel forming region VL1 is made greater than the channel length (length FL2) of the oxidized channel forming region VL2, the negative shift in threshold value and the hump characteristics can be prevented from occurring. Thus, the degradation of the characteristics of the transistor TR can be suppressed.

In Configuration Example 2 as well, advantageous effects similar to those of Embodiment 1 can be obtained.

### Embodiment 2

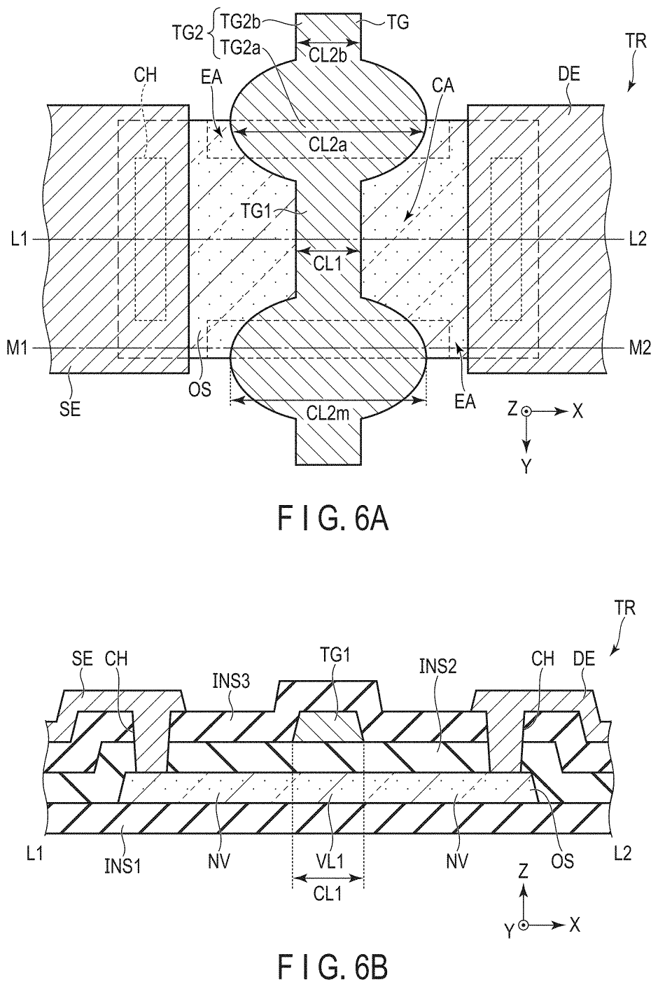

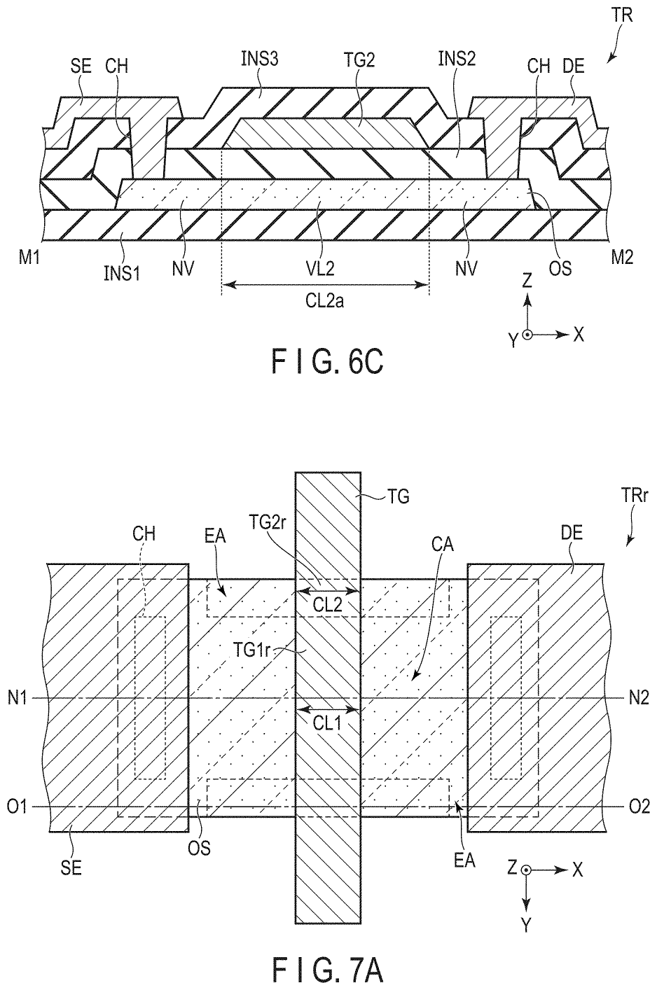

FIG. 6A is a plan view schematically showing an example of the transistor of Embodiment 2. FIG. 6B is a cross-sectional view of the transistor taken along line L1-L2 shown in FIG. 6A. FIG. 6C is a cross-sectional view of the transistor taken along line M1-M2 shown in FIG. 6A.

In Embodiment 2, unlike Embodiment 1, the length of the channel forming region formed in the region EA in an end portion of the oxide semiconductor layer OS is made greater than the length of the channel forming region formed in the region CA in the vicinity of the central portion. For example, in the etching process of the oxide semiconductor layer OS or the etching of the electrode, the region EA in the end portion of the oxide semiconductor layer OS may become insufficiently oxidized. In such a case, the length of the channel forming region formed in the region EA is increased, and thus the negative shift of the threshold value and the hump characteristics can be prevented. Thus, it is possible to suppress the deterioration of the characteristics of the transistor TR.

The transistor TR comprises an insulating layer INS1, an oxide semiconductor layer OS, an insulating layer INS2, a gate electrode TG, an insulating layer

INS3, a source electrode SE and a drain electrode DE. The gate electrode TG is provided between the source electrode SE, the drain electrode DE and the oxide semiconductor layer OS.

The gate electrode TG extends along the second direction Y and overlaps the oxide semiconductor layer OS. The gate electrode TG includes a region TG1 which overlaps the region CA near the central portion of the oxide semiconductor layer OS and a region TG2 which overlaps the region EA near the end portion. The region TG1 has a rectangular shape.

The region TG2 includes regions TG2a and TG2b. The region TG2a has a shape in which an ellipse is partially cut by a string. As shown in FIG. 6A, the region TG2a has an elliptic shape in which top and bottom portions thereof are cut by a string with respect to the surface of the page. The region TG2b has a rectangular shape. In other words, the region TG2 has a shape in which a rectangular shape is placed between the two portions of the ellipse cut by a string.

In the gate electrode TG, the regions TG2b, TG2a, TG1, TG2a and TG2b are arranged along the second direction Y. These regions should be formed from metal layers integrated into one body.

In the regions TG1, TG2a and TG2b, the lengths along the first direction X are respectively CL1, CL2a, and CL2b, respectively. The lengths CL1 and CL2b are constant. The length CL2a varies along the second direction Y. The length CL2a takes the maximum length

CL2m when passing through the center of the ellipse described above. In FIG. 6A, an edge of the oxide semiconductor layer OS and the center of the ellipse overlap each other. In other words, the length of the region TG2a which overlaps the edge of the oxide semiconductor layer OS is the maximum length CL2m.

In the oxide semiconductor layer OS of Embodiment 2, the region of the gate electrode TG, which overlaps the region TG1 is defined as the channel forming area VL1, the area which overlaps the region TG2a is defined as the channel forming area VL2, and the region which does not overlap with the gate electrode TG is defined as the region NV. The lengths CL1 and CL2a are, respectively, the channel length of the channel forming region VL1 and the channel length of the channel forming region VL2. In other words, the lengths CL1 and CL2a correspond, respectively, to the channel length of the channel forming region in the region CA and the channel length of the channel forming region in area EA.

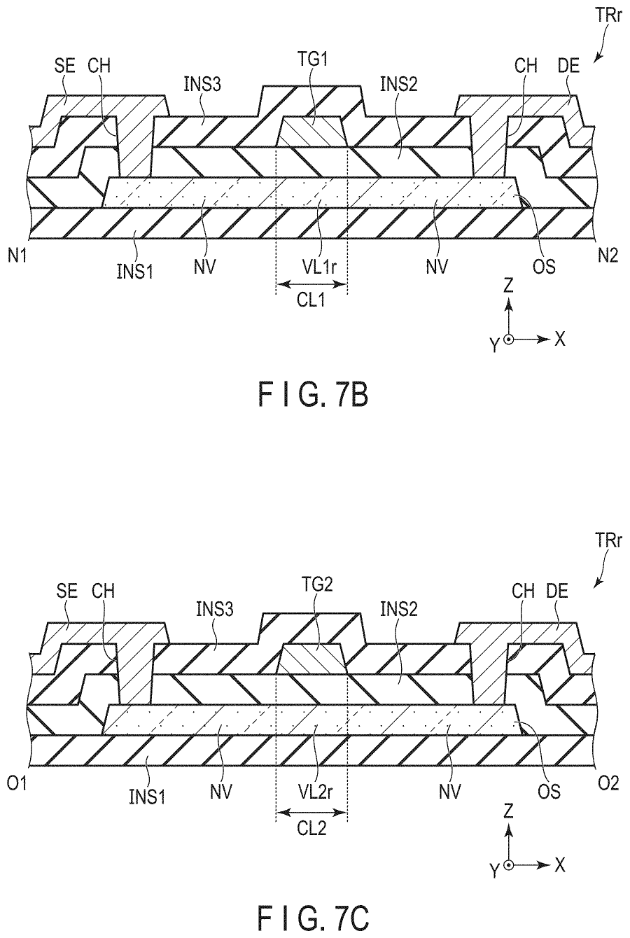

FIG. 7A is a plan view schematically showing an example of a transistor of Comparative Example 3. FIG. 7B is a cross-sectional view of the transistor taken along line N1-N2 shown in FIG. 7A. FIG. 7C is a cross-sectional view of the transistor taken along line 01-02 shown in FIG. 7A. The gate electrode TG of the transistor TRr in Comparative Example 3 has a constant length at all time along the first direction X.

Of the gate electrode TG, the region which overlaps the region CA is defined as TG1r, and the region which does not overlap the region CA but overlaps the region EA is defined as TG2r. The lengths of the regions TGlr and TG2r along the first direction

X are defined as CL1 and CL2, respectively. The lengths CL1 and CL2 are equal to each other.

In the oxide semiconductor layer OS, the region which overlaps the region TGlr is the channel forming regions VL1r, and the region which overlaps the region TG2r is the channel forming region VL2r. In other words, the transistor TRr includes two transistors, each of which includes channel forming regions VL1r and

VL2r having different degrees of oxidation, respectively.

In the transistor including the under-oxidized channel forming region VL2r, a parasitic channel may be created, resulting in negatively shifting of the threshold value, which is undesirable. As a result, the threshold voltages of the two transistors may become undesirably different from each other. This may cause hump characteristics, in which a bend appears in the voltage-current characteristics of the transistor

TRr. Therefore, the characteristics of the transistor TRr as a whole may undesirably deteriorate.

In Embodiment 2, when the region EA in the end portion of the oxide semiconductor layer OS becomes insufficiently oxidized, for example, due to the etching process, the length CL2 where the region EA of the end portion and the gate electrode TG overlap each other, can be increased. Thus, the length of the channel forming region VL2 can be increased. In Embodiment 2, it is also possible to suppress the occurrence of hump characteristics of the transistor and variation in threshold value.

### <Configuration Example 3>

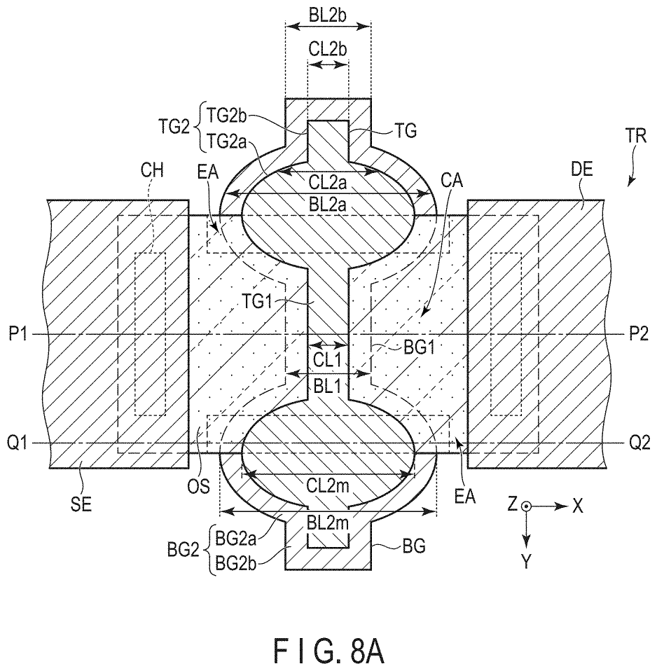

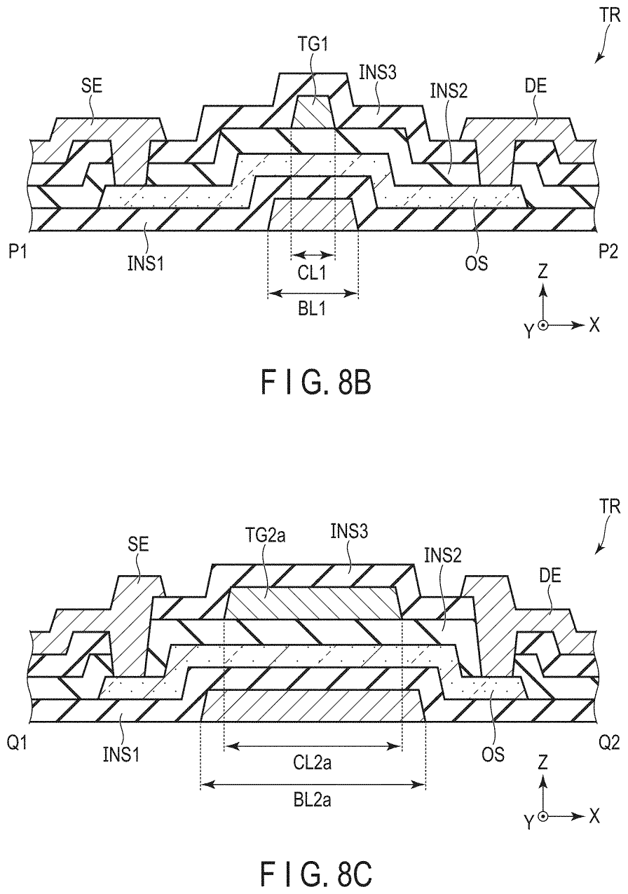

FIG. 8A is a plan view of another configuration example of the transistor in Embodiment 2. The configuration example shown in FIG. 8A is different from that of FIG. 6A in that it includes a bottom gate in addition to the top gate.

FIG. 8B is a cross-sectional view of the transistor taken along line P1-P2 shown in FIG. 8A. FIG. 8C is a cross-sectional view of the transistor taken along line Q1-Q2 shown in FIG. 8A. In this configuration example, mainly the points which differ from those of Embodiment 1 will be explained.

The transistor TR comprises a gate electrode BG, an insulating layer INS1, an oxide semiconductor layer OS, an insulating layer INS2, a gate electrode TG, an insulating layer INS3, a source electrode SE and a drain electrode DE. The oxide semiconductor layer OS is provided between the gate electrodes BG and TG.

The gate electrode BG has a shape one size larger than that of the gate electrode TG. The gate electrode BG includes a region BG1 which overlaps the region CA near the central portion of the oxide semiconductor layer OS, and a region BG2 which overlaps the region EA near the end portion. The region BG1 has a rectangular shape.

The region BG2 includes regions BG2a and TG2b.

The region BG2a has a shape in which a portion of an ellipse is cut by a string. As shown in FIG. 8A, the region BG2a has an elliptic shape in which top and bottom portions thereof are cut by a string with respect to the surface of the page. The region BG2b has a rectangular shape.

In the gate electrode BG, the regions BG2b, BG2a, BG1, BG2a and BG2b are arranged along the second direction Y. These regions should be formed of metal layers integrated into one body.

In the regions BG1, BG2a and BG2b, the lengths thereof along the first direction X are respectively defined as BL1, BL2a and BL2b. The lengths BL1 and BL2b are constant. The length BL2a varies along the second direction Y. The length BL2a takes the maximum length BL2m, which passes through the center of the ellipse mentioned above. In FIG. 8A, the edge of the oxide semiconductor layer OS and the center of the above ellipse overlap each other. That is, the length of the region BG2a which overlaps the edge of the oxide semiconductor layer OS is the maximum length BL2m.

The gate electrode TG shown in FIG. 8A has a shape similar to that of the gate electrode TG shown in FIG. 6A. The regions TG1, TG2a and TG2b overlap the regions BG1, BG2a and BG2b, respectively.

As shown in FIG. 8B, the end portion of the region BG1 and the end portion of the region TG1 do not coincide with each other in cross-sectional view. As shown in FIG. 8C, the end portion of the region BG2a and the end portion of the region TG2a do not coincide with each other in cross-sectional view. Although not shown in the figure, the end portion of the region BG2b and the end portion of the region TG2b do not coincident with each other in cross-sectional view.

The length BL1 is greater than the length CL1 at the same location along the second direction Y. The length BL2a is greater than the length CL2a. The maximum length BL2m is greater than the maximum length CL2m. The length BL2b is greater than the length CL2b.

If the end portion of the gate electrodes BG (the regions BG1 and BG2) and that of the gate electrodes TG (the regions TG1 and TG2) coincide with each other, a large step is formed, which may cause a decrease in the reliability of transistor TR, and the like. Therefore, it is preferable that these end portions do not coincide with each other.

The gate electrode BG should be formed of a material similar to that of the gate electrode TG. When the gate electrode BG is formed of a metal material, the gate electrode BG functions as a light-shielding layer which shields the channel forming region. The voltage to be applied to the gate electrode BG may be the same voltage as that of the gate electrode TG or may be a fixed voltage. In Configuration Example 3, functions similar to those of Embodiment 2 are exhibited.

### <Configuration Example 4>

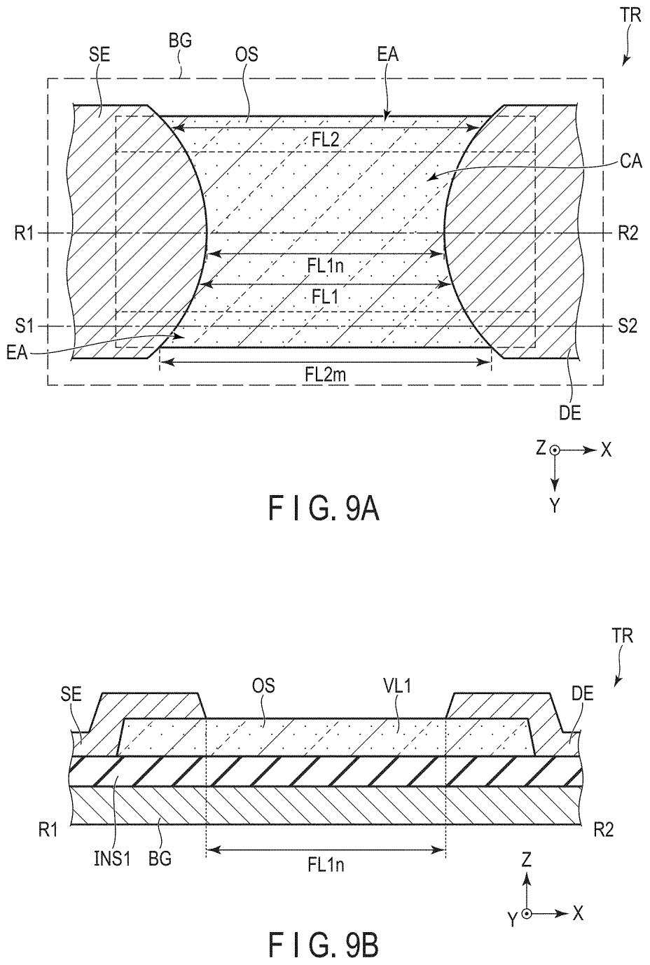

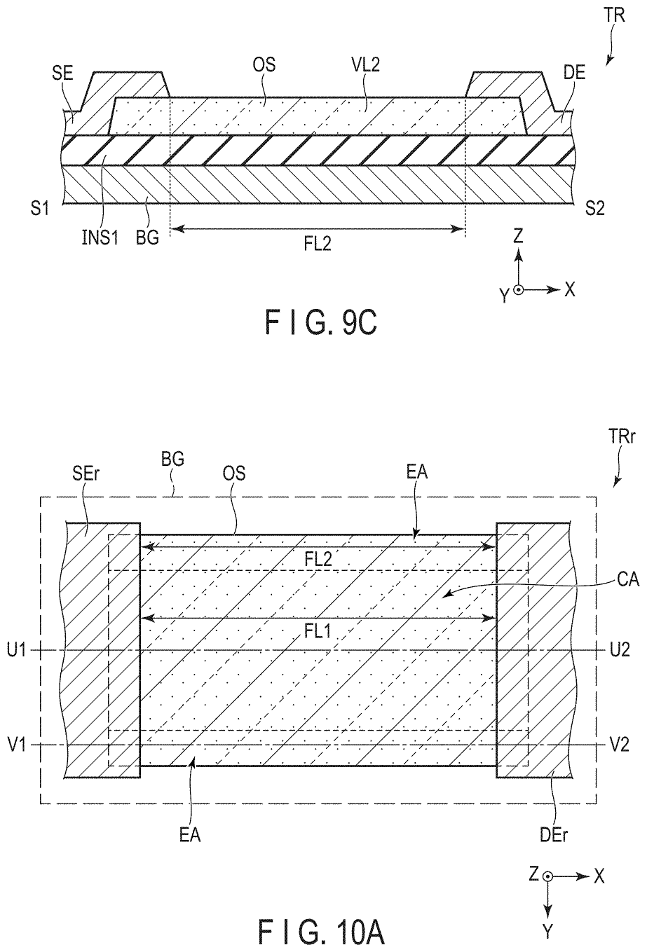

FIG. 9A is a plan view of still another configuration example of the transistor in Embodiment 2. The configuration example shown in FIG. 9A is different from that of FIG. 6A in that it does not include a top gate but include only a bottom gate.

FIG. 9B is a cross-sectional view of the transistor taken along line R1-R2 shown in FIG. 9A. FIG. 9C is a cross-sectional view of the transistor taken along line S1-S2 shown in FIG. 9A.

The transistor TR comprises a gate electrode BG, an insulating layer INS1, a source electrode SE and a drain electrode DE.

The insulating layer INS1 is provided on the gate electrode BG. On the insulating layer INS1, an oxide semiconductor layer OS is provided. The oxide semiconductor layer OS opposes the gate electrode BG1 while interposing the insulating layer INS1 therebetween. The entire oxide semiconductor layer OS overlaps the gate electrode BG.

The source electrode SE and the drain electrode DE are each provided in contact with the oxide semiconductor layer OS. The source electrode SE and the drain electrode DE each have a shape in which a semi-circle is added on a rectangle. As shown in FIG. 9A, the source electrode SE has a shape a semi-circle is added to a right side of a rectangle with respect to the direction of viewing on the surface of the page, whereas the drain electrode DE has a shape a semi-circle is added to a left side of a rectangle with respect to the direction of viewing on the surface of the page. Note that arcs of the two circles oppose each other.

The length between the source electrode SE and the drain electrode DE varies along the second direction Y. The length between the source electrode SE and the drain electrode DE in the region CA described above is defined as FL1. The length between the source electrode SE and the drain electrode DE in the region EA is defined as FL2. The minimum length of the length FL1 is defined as FL1n. Assuming that each of the above-described arcs opposing each other forms a circle, the length through the centers of the circles is FL1n.

Of the length FL2, the length which overlaps the edge of the oxide semiconductor layer OS is the maximum length FL2m. At the boundary between the region CA and the region EA, the lengths FL1 and FL2 are equal to each other.

In FIGS. 9A, 9B and 9C, the region of the oxide semiconductor layer OS, which overlaps the gate electrode BG and is located between the source electrode SE and drain electrode DE is the channel forming region. The lengths FL1, FL1n, FL2 and FL2m are respectively the channel length of the channel forming region in the region CA, the minimum length of the channel forming region in the region CA, the channel length of the channel forming region in the region EA and the maximum channel length of the channel forming region in the region EA.

In Configuration Example 4, the length FL2, which is the channel length of the under-oxidized channel forming region VL2, is made greater than or equal to the channel length FL1, which is the channel length of the oxidized channel forming region VL1. Thus, negative shift of the threshold value and the hump characteristics can be prevented. Therefore, the occurrence of the negative shift of the threshold value and the hump characteristics can be prevented. In this manner, it is possible to suppress the degradation of the characteristics of the transistor TR.

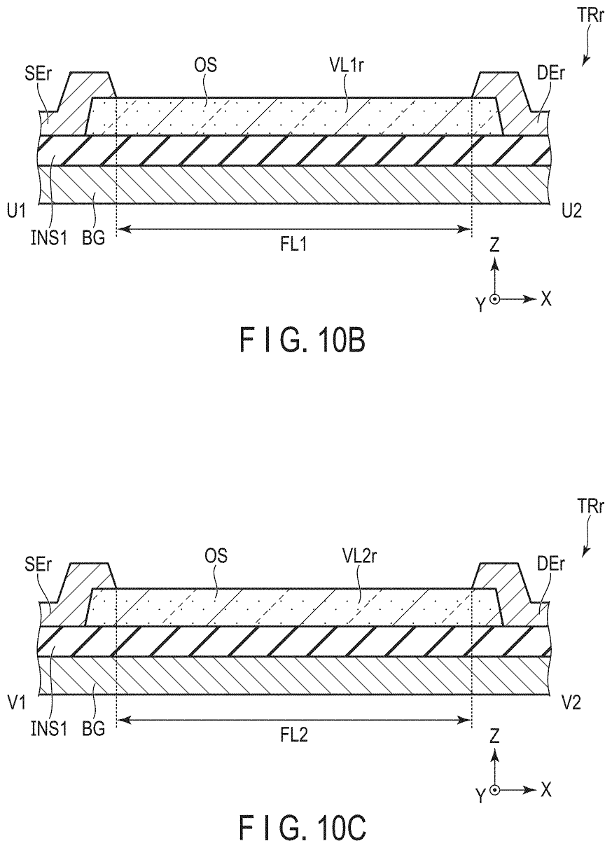

FIG. 10A is a plan view schematically showing an example of a transistor of Comparative Example 4. FIG. 10B is a cross-sectional view of the transistor taken along line U1-U2 shown in FIG. 10A. FIG. 10C is a cross-sectional view of the transistor taken along line V1-V2 shown in FIG. 10A. In Comparative Example 4, the length between the source electrode SEr and the drain electrode of the transistor TRr along the first direction X is constant at all times.

Between the source electrode SEr and the drain electrode DEr, the region which overlap the region CA is the channel forming regions VLlr, and the region which overlap the region EA is the channel forming regions VL2r. In other words, the transistor TRr includes two transistors, each of which contains channel forming regions VLlr and VL2r having different degrees of oxidation.

In the transistor including the under-oxidized channel forming region VL1r, a parasitic channel may be created, resulting in negatively shifting of the threshold value, which is undesirable. As a result, the threshold voltages of the two transistors may become undesirably different from each other. This may cause hump characteristics, in which a bend appears in the voltage-current characteristics of the transistor TRr. Therefore, the characteristics of the transistor TRr as a whole may undesirably deteriorate.

In Configuration Example 4, as in the case of Embodiment 2, the length FL2, which is the channel length of the under-oxidized channel forming region VL2, is made greater than or equal to the channel length FL1, which is the channel length of the oxidized channel forming region VL1. Thus, negative shift of the threshold value and the hump characteristics can be prevented. Therefore, it is possible to suppress the degradation of the characteristics of the transistor TR.

In Configuration Example 4 as well, advantageous effects similar to those of Embodiment 2 can be exhibited.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The following appendix includes inventions described in the original claims of this application.

(A1)

A transistor comprising:
a gate electrode;
an oxide semiconductor layer which overlaps the gate electrode and including a central portion and an end portion;

an insulating layer provided between the gate electrode and the oxide semiconductor layer; and

a source electrode and a drain electrode each connected to the oxide semiconductor layer, wherein an oxidation degree of the end portion is lower than an oxidation degree of the central portion; and a length between the source electrode and the drain electrode in the end portion is greater than a length between the source electrode and the drain electrode in the central portion.

(A2)

The transistor according to item (A1), wherein the oxide semiconductor layer is provided between the source electrode and the drain electrodes, and the gate electrode.

(A3)

The transistor according to item (A1), wherein the source electrode and the drain electrode each have a shape in which a semi-circle is added to a rectangle. (Bl)

A transistor comprising:
a gate electrode;
an oxide semiconductor layer which overlaps the gate electrode and includes a first region and a second region;
an insulating layer provided between the gate electrode and the oxide semiconductor layer; and
a source electrode and a drain electrode each connected to the oxide semiconductor layer, wherein
an oxidation degree of the first region is lower than an oxidation degree of the second region, and
a first channel length of a first channel forming region in the first region is greater than a second channel length of a second channel forming region in the second region.

What is claimed is:

1. A transistor comprising:
a gate electrode;
an oxide semiconductor layer which overlaps the gate electrode and including a central portion and an end portion;
an insulating layer provided between the gate electrode and the oxide semiconductor layer; and
a source electrode and a drain electrode each connected to the oxide semiconductor layer, wherein
an oxidation degree of the end portion is lower than an oxidation degree of the central portion, and
a length of the gate electrode overlapping the central portion is greater than a length of the gate electrode overlapping the end portion.

2. The transistor according to claim 1, wherein the gate electrode is provided between the source electrode and the drain electrode, and the oxide semiconductor layer.

3. The transistor according to claim 1, further comprising:
a second gate electrode opposing the gate electrode when taken as a first gate electrode, wherein
the oxide semiconductor layer is provided between the first gate electrode and the second gate electrode.

4. The transistor according to claim 1, wherein the gate electrode has a shape in which a portion of a circle is cut by a string.

5. The transistor according to claim 3, wherein the first gate electrode and the second gate electrode each have a shape in which a portion of a circle is cut by a string, and
the second gate electrode is larger than the first gate electrode.

6. A transistor comprising:
a gate electrode;
an oxide semiconductor layer overlapping the gate electrode and including a central portion and an edge portion;
an insulating layer between the gate electrode and the oxide semiconductor layer; and
a source electrode and a drain electrode each connected to the oxide semiconductor layer, wherein
an oxidation degree of the central portion is lower than an oxidation degree of the end portion, and
a length between the source electrode and the drain electrode in the central portion is greater than a length between the source electrode and the drain electrode in the end portion.

7. The transistor according to claim 6, wherein the oxide semiconductor layer is provided between the source electrode and the drain electrode, and the gate electrode.

8. The transistor according to claim 6, wherein the source electrode and the drain electrode each have a shape in which a portion of a rectangle is notched with an arc.

9. A transistor comprising:
a gate electrode;
an oxide semiconductor layer which overlaps the gate electrode and including a central portion and an end portion;
an insulating layer provided between the gate electrode and the oxide semiconductor layer; and
a source electrode and a drain electrode each connected to the oxide semiconductor layer, wherein
an oxidation degree of the end portion is lower than an oxidation degree of the central portion, and
a length of the gate electrode which overlaps the end portion is greater than a length of the gate electrode which overlaps the central portion.

10. The transistor according to claim 9, wherein
the gate electrode is provided between the source electrode and the drain electrode, and the oxide semiconductor layer.

11. The transistor according to claim 9, further comprising:
a second gate electrode opposing the gate electrode when taken as a first gate electrode, wherein
the oxide semiconductor layer is provided between the first gate electrode and the second gate electrode.

12. The transistor according to claim 9, wherein
the gate electrode has a shape in which a rectangle is arranged between two ellipses partially cut by a string.

13. The transistor according to claim 11, wherein
the first gate electrode and the second gate electrode each have a shape in which a rectangle is arranged between two ellipses partially cut by a string, and
the second gate electrode is larger than the first gate electrode.
